(19) United States
(12) Patent Application Publication
(10) Pub. No.: US 2024/0365503 A1
(43) Pub. Date: Oct. 31, 2024

(54) COLDPLATE SYSTEM AND COOLING ARRANGEMENT

(71) Applicant: Rohde & Schwarz GmbH & Co. KG, Munich (DE)

(72) Inventors: Johannes BRAUN, Deggendorf (DE); Alexander STUKA, Hengersberg (DE); Andreas GEISS, Bischofsmais (DE); Maximilian FINKLER, Moenchsdeggingen (DE); Valentin LASKA, Munich (DE)

(73) Assignee: Rohde & Schwarz GmbH & Co. KG, Munich (DE)

(21) Appl. No.: 18/308,799

(22) Filed: Apr. 28, 2023

(51) Int. Cl. H05K 7/20; H05K 1/02

(52) U.S. Cl. CPC H05K 7/20254; H05K 1/0203; H05K 7/2039

(57) ABSTRACT

The present disclosure relates to a coldplate system. The coldplate system comprises at least one opening in a coldplate, and at least one heat sink is inserted through the at least one opening and is connected to the coldplate via resilient mounting means. In this regard, the at least one heat sink is provided with a heat transfer surface and an end with a heat dissipation structure. Furthermore, the heat dissipation structure is arranged within a space enclosed by the coldplate. Moreover, the resilient mounting means are configured to resiliently bias the heat transfer surface against a surface to be cooled when the coldplate system is mounted onto the surface.

### TECHNICAL FIELD

The disclosure relates to a coldplate system and a cooling arrangement, especially for the cooling of components at board level.

### BACKGROUND ART

Generally, coldplates may be directly affixed to a heat-producing piece of equipment in order to remove or dissipate the generated heat. In this regard, the cooling efficiency of such coldplates should be high and the coldplates should be securely sealed onto the piece of equipment to be cooled.

In order to achieve the lowest possible contact resistance and compensation of tolerances, the contact pressure onto the heating surface of the piece of equipment to be cooled should be sufficiently high. Commonly, individual coldplates are used for mounting on the heat-generating elements, especially coldplates for small-size components without bias force.

### SUMMARY

In view of the above, there is a need to provide an improved coldplate system and an improved cooling arrangement, especially at the board level, to facilitate a pre-tensioning force to achieve a high contact pressure at the contact surface of the heat-generating element, as well as to facilitate the cooling of other peripherals.

According to a first aspect of this disclosure, a coldplate system is provided. The coldplate system comprises at least one opening in a coldplate, and at least one heat sink is inserted through the at least one opening and is connected to the coldplate via resilient mounting means. In this regard, the at least one heat sink is provided with a heat transfer surface and an end with a heat dissipation structure. Furthermore, the heat dissipation structure is arranged within a space enclosed by the coldplate. Moreover, the resilient mounting means are configured to resiliently bias the heat transfer surface against a surface to be cooled when the coldplate system is mounted onto the surface.

In other words, the heat sink may be preloaded by means of the resilient mounting means in the direction of a surface or a surface of a component to be cooled. Advantageously, the heat sink can be pressed with a pre-tensioning force in the direction of the surface or the component to be cooled via the resilient mounting means.

In an implementation form of the first aspect, the coldplate further comprises a cooling fluid, an inlet, and an outlet, the cooling fluid being configured to flow through the coldplate via the inlet and the outlet. In this regard, the cooling fluid is configured to flow through the heat dissipation structure of the at least one heat sink.

For example, the heat dissipation structure may comprise or be a bellows type structure of an array of thin plates or fins, or a needle type structure with an array of rods. The flow rate of the cooling fluid or coolant through the coldplate as well as through the heat dissipation structure of the heat sink may be regulated or controlled externally, e.g., via a pump or a fan, with or without the aid of a heat exchanger.

In an implementation form of the first aspect, the coldplate system further comprises a first sealing arrangement between the at least one opening in the coldplate and the at least one heat sink, the first sealing arrangement being configured to attach the at least one heat sink to the coldplate in a fluid-tight manner. Advantageously, the first sealing arrangement may prevent any leakage of the cooling fluid through the heat sink opening while allowing the heat sink to move.

In an implementation form of the first aspect, the coldplate system further comprises a first retaining arrangement configured to retain the at least one heat sink to the coldplate corresponding to the at least one opening.

For example, the first retaining arrangement may comprise or be one or more retaining screws. The first retaining arrangement may advantageously prevent the heat sink from falling out of the coldplate after assembly.

In an implementation form of the first aspect, the at least one heat sink further comprises one or more grooves for a first sealing arrangement between the at least one opening and the at least one heat sink, one or more supports for the resilient mounting means, and one or more recesses for a first retaining arrangement.

For example, the heat sink may be pre-modeled or constructed, especially corresponding to the surface to be cooled. In particular, the heat transfer surface and/or the heat dissipation structures, especially of the shape and/or the dimension, may correspond to the surface to be cooled. The heat sink may be made of metal (e.g., copper) or metal alloys (e.g., aluminum alloys).

In an implementation form of the first aspect, the coldplate further comprises a first surface comprising the at least one opening, a second surface configured to conceal the cooling fluid within the space enclosed by the coldplate, and a second sealing arrangement configured to attach the first surface and the second surface in a fluid-tight manner. Advantageously, the fluid-tight arrangement may prevent any leakage of the cooling fluid through the joint between the first surface and the second surface.

In an implementation form of the first aspect, the first surface and/or the second surface comprises a plurality of guiding fins configured to control a flow of the cooling fluid within the coldplate.

Advantageously, a targeted or guided flow of the cooling fluid, especially towards the heat dissipation structure, can be achieved. Additionally, a more homogeneous flow of the cooling fluid, especially through the heat dissipation structure, can be achieved, which may result in a higher heat dissipation.

In an implementation form of the first aspect, the first surface and/or the second surface comprises one or more flow divider configured to form respective flow channels for the cooling fluid within the coldplate. Advantageously, a targeted division and distribution of the cooling fluid, especially corresponding to the heat dissipation structure, can be achieved, which may further enhance the heat dissipation rate.

In an implementation form of the first aspect, the coldplate further comprises a second retaining arrangement configured to retain the second surface to the first surface. For example, the second retaining arrangement may comprise or be one or more retaining screws, or one or more welding joints, or a combination thereof.

In an implementation form of the first aspect, the first surface comprises a peripheral segment protruding towards the surface to be cooled.

For example, the coldplate may have a dimension larger than the dimension of the surface to be cooled, especially with walls going or protruding towards the surface to be cooled. This may achieve the advantage of providing additional shielding, e.g., Electromagnetic Compatibility (EMC) shielding for Electromagnetic Interference (EMI), of the surface or the components.

In an implementation form of the first aspect, the cooling fluid comprises or is a liquid cooling fluid (e.g., water, deionized water, inhibited glycol, dielectric fluids) and/or a gaseous cooling fluid (e.g., air, hydrogen, inert gases).

In an implementation form of the first aspect, the resilient mounting means comprise or is a spring or a plurality of springs with variable pre-tensioning forces.

For example, the resilient mounting means may comprise or be a single spring with a large diameter, or a plurality of springs with a small diameter, especially designed to provide the pre-tensioning force.

According to a second aspect of this disclosure, a cooling arrangement is provided. The cooling arrangement comprises the coldplate system according to the first aspect, and a printed circuit board comprising at least one element to be cooled. In this regard, the resilient mounting means are configured to resiliently bias the heat transfer surface of the at least one heat sink against a surface of the at least one element to be cooled when the coldplate system is mounted onto the printed circuit board.

Advantageously, an improved cooling arrangement can be achieved by means of the coldplate with recesses for modular concealable heat sinks and respective resilient mounting means, which may result in the integration of said modular heat sinks over the entire printed circuit board (PCB) surface while simultaneously cooling other PCB peripherals.

In an implementation form of the second aspect, the at least one element comprises or is a high power density integrated circuit. For instance, the element may comprise or be graphics processor units (GPUs), field programmable gate arrays (FPGAs), and the like.

It is to be noted that the cooling arrangement according to the second aspect corresponds to the coldplate system according to the first aspect and its implementation forms. Accordingly, the cooling arrangement of the second aspect may have corresponding implementation forms. Further, the cooling arrangement of the second aspect achieves the same advantages and effects as the coldplate system of the first aspect and its respective implementation forms.

### BRIEF DESCRIPTION OF THE DRAWINGS

The above described aspects and implementation forms will be explained in the following description of specific embodiments in relation to the enclosed drawings, in which:

FIG. 1 shows an exploded view of an exemplary coldplate system;

FIG. 2 shows an isometric view of the exemplary coldplate system;

FIG. 3 shows a top view of the exemplary coldplate system;

FIG. 4 shows a sectional view of the exemplary coldplate system; and

FIG. 5 shows an exemplary cooling arrangement.

### DETAILED DESCRIPTION OF EMBODIMENTS

Reference will now be made in detail to the embodiments of the present disclosure, examples of which are illustrated in the accompanying drawings. However, the following embodiments of the present disclosure may be variously modified and the range of the disclosure is not limited by the following embodiments. Reference signs for similar entities in different embodiments are partially omitted.

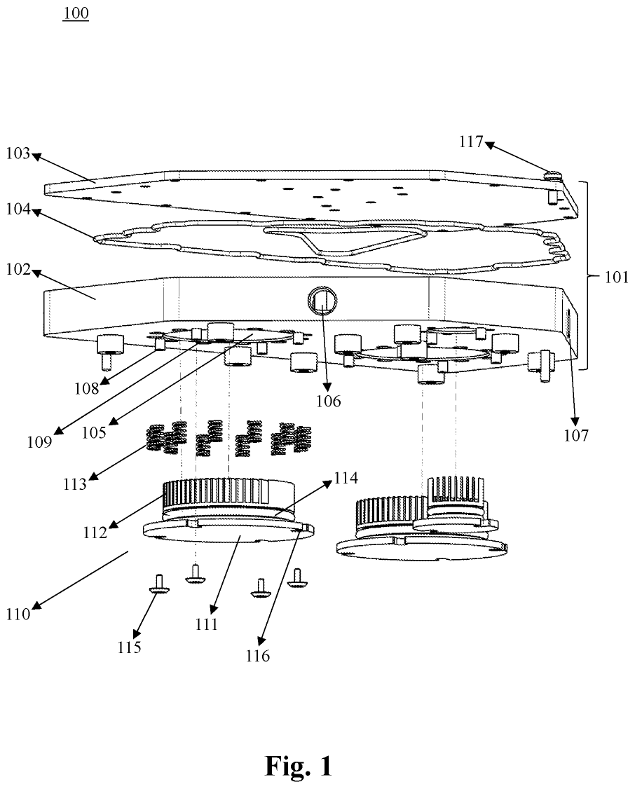

In FIG. 1, an exploded view of an exemplary coldplate system 100 is illustrated. The coldplate system 100 may comprise a coldplate 101 comprising a first surface or bottom surface 102 and a second surface or top surface 103 with a space enclosed in-between. The first surface 102 and the second surface 103 may be sealed together via a sealing arrangement 104 (e.g., elastomer seal, silicon seal, and the like).

The first surface 102 may comprise an opening or recess 105 corresponding to a shape and/or dimension of a heat sink 110 to be inserted though the opening 105. The first surface 102 may further comprise, especially along a wall confining the enclosed space of the coldplate 101, an inlet 106 and an outlet 107 to facilitate the intake and the exhaust of a coolant through the coldplate 101, especially through the enclosed space of the coldplate 101.

The first surface 102 may further comprise, especially along the opening 105, supports 108 for retaining screws 115 and recesses 109 for springs 113.

The coldplate system 100 may further comprise one or more heat sinks 110, herein exemplarily illustrated three heat sinks with different sizes or dimensions. The heat sink 110 may comprise a heat transfer surface 111 and a heat dissipation structure 112. The heat sink 110 may be arranged or inserted through the opening 105 of the first surface 102 in a press-fit manner such that the heat dissipation structure 112 may be arranged within the enclosed space of the coldplate 101.

The coldplate system 100 may further comprise springs 113, herein exemplarily illustrated twelve springs, which may be arranged such that the heat sink 110 is connected to the coldplate 101 via the springs 113. For example, the heat sink 110 may be provided with supports for the springs 113 and the springs 113 may be arranged between the supports of the heat sink 110 and the recesses 109 along the opening 105 of the first surface 102.

The heat sink 110 may further comprise grooves for a sealing arrangement 114 (e.g., elastomer seal, silicon seal, and the like), especially arranged along the grooves of the heat sink 110 such that the heat sink 110 can be fitted through the opening 105 in a fluid-tight manner. The heat sink 110 may further comprise recesses 116 so that the retaining screws 116 may retain the heat sink 110 to the opening 105 via the recess 116 and the supports 108.

The coldplate 101 may comprise further retaining screws 117 in order to retain the second surface 103 onto the first surface 102. As such, by means of the sealing arrangement 104 and the retaining screws 117, the first surface 102 and the second surface 103 can be fitted together in a fluid-tight manner.

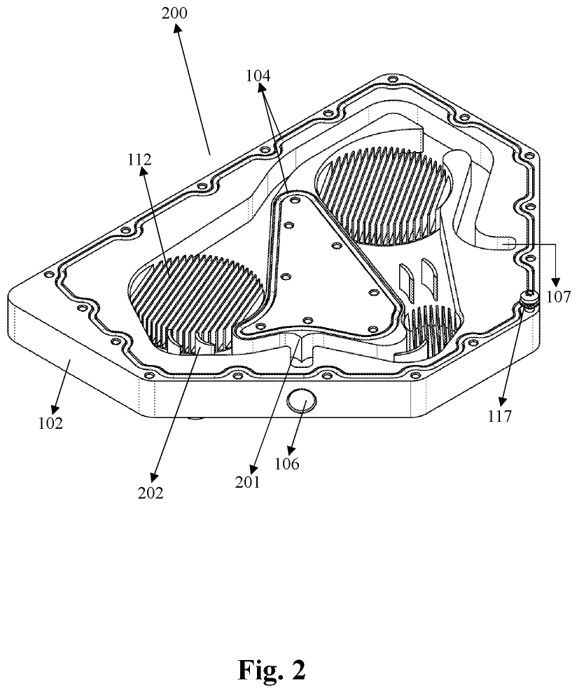

In FIG. 2, an isometric view of the coldplate system 100 is illustrated. In particular, the enclosed space 200 of the coldplate 101 is shown in detail. Within the enclosed space 200, it can be seen that the heat dissipation structure 112 of the heat sink 110 may be arranged in a protruding manner, i.e., protruding through the opening 105 of the first surface 102.

The sealing arrangement 104, the inlet 106, the outlet 107, and the retaining screw 117 can also be seen with respect to the first surface 102.

As illustrated herein, the first surface 102 may be provided with a flow divider or flow dividing structure 201, especially within the enclosed space 200, so as to produce flow channels for the cooling fluid. Although it is exemplarily shown that the flow divider is realized on the first surface 102, it is also possible that the flow divider 201 may be realized on the second surface 103 (e.g., projecting towards the enclosed space 200).

Further alternatively, the flow divider 201 may be realized in parts on both of the first surface 102 (e.g., parts growing within the enclosed space 200) and the second surface 103 (e.g., parts projecting towards the enclosed space 200).

Furthermore, the first surface 102 may be provided with guiding fins 202, herein exemplarily illustrated five guiding fins, in order to control the flow of the cooling fluid within the enclosed space 200. Although it is exemplarily shown that the guiding fins 202 are realized on the first surface 102, it is also possible that the guiding fins 202 may be realized on the second surface 103 (e.g., projecting towards the enclosed space 200).

Further alternatively, the guiding fins 202 may be realized in parts on both of the first surface 102 (e.g., parts growing within the enclosed space 200) and the second surface 103 (e.g., parts projecting towards the enclosed space 200).

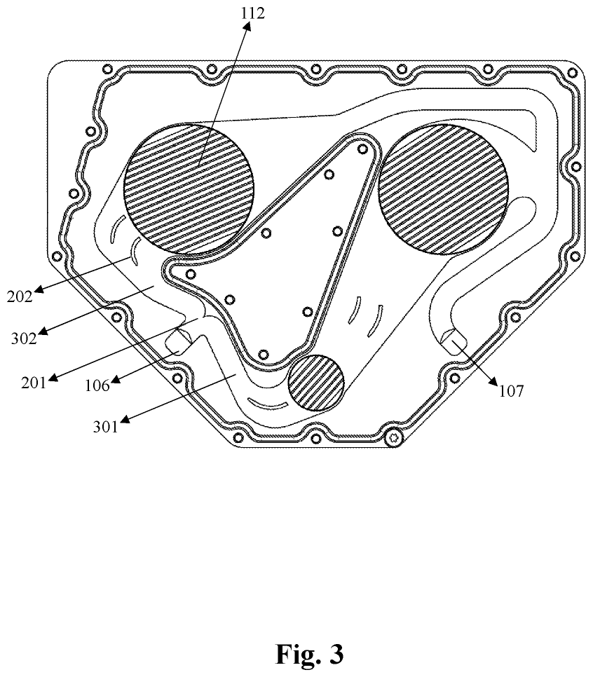

In FIG. 3, a top view of the coldplate system 100 is illustrated. In particular, the flow control of the cooling fluid within the coldplate 101 is shown in detail. For instance, the flow divider 201 may be arranged in line with the inlet 106 so that the flow of the cooling fluid can be divided along flow channels 301, 302. The flow channels 301, 302 may be formed based on the positions of the heat sinks 110, i.e., the positions of the heat dissipation structures 112, to achieve a homogeneous flow through the heat dissipation structures 112.

As illustrated herein, the cooling fluid coming into the coldplate 101 through the inlet 106 may be divided into two flow channels 301, 302 by the flow divider 201. The flow of the cooling fluid along the flow channel 302 may be controlled or guided by the guiding fins 202 and may exit the coldplate 101 through the outlet 107 so that the heat dissipation structure 112 may experience a more targeted and homogeneous flow.

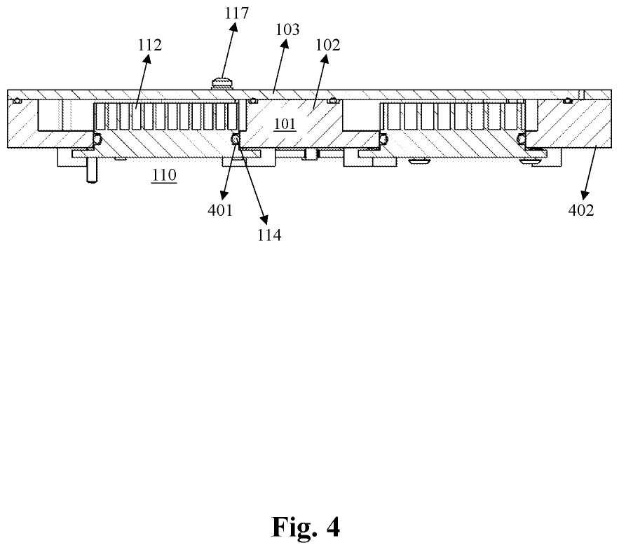

In FIG. 4, a sectional view of the coldplate system 100 is illustrated. It can be seen that the second surface 103 may be fixed in relation to the first surface 102 and may be retained via the retaining screw 117. It can further be seen that the heat sink 110 may be arranged in relation to the coldplate 101 such that the heat dissipation structure 112 may reside inside of the coldplate 101 and the heat transfer surface 111 may face towards the surface to be cooled. Furthermore, the grooves 401 on the heat sink 110 can also be seen for the sealing arrangement 114, as well as the sealing arrangement 114 along the grooves 401.

In addition, the first surface 102 may comprise a peripheral segment, e.g. a segment or wall 402, protruding towards the surface to be cooled. For example, the first surface 102 may be provided with walls going downwards or protruding towards the surface to be cooled, which may provide additional EMC shielding of the surface or the components.

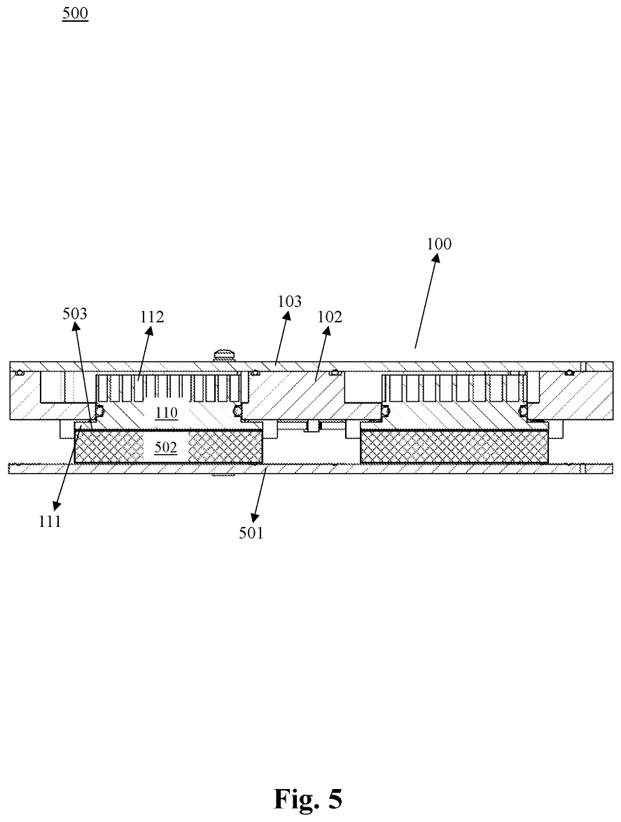

In FIG. 5, an exemplary cooling arrangement 500 is illustrated. In particular, a sectional view of the cooling arrangement 500 is shown herein. The cooling arrangement 500 may comprise the coldplate system 100 and a PCB 501, where the coldplate system 100 may be arranged onto the PCB 501. In this regard, the PCB 501 may comprise PCB components 502, e.g., GPUs, FPGAs, to be cooled.

The coldplate system 100 may be arranged or mounted onto the PCB 501 such that a heat sink 110 may be mounted onto a corresponding PCB component 502. In other words, the resilient mounting means 113 may resiliently bias the heat transfer surface 111 of the heat sink 110 against a surface 503 of the PCB component 502.

Furthermore, thermal interface materials, such as gap pads or phase change pastes, may be arranged or applied between the heat transfer surface 111 of the heat sink 110 and the surface 503 of the PCB component 502.

Due to the variable contact pressure supported by the resilient mounting means 113, the thermal interface materials can be pressurized in order to reduce the thermal resistance between the heat transfer surface 111 of the heat sink 110 and the surface 503 of the PCB component 502. Moreover, the tolerances of the underlying components, e.g., surface roughness, flatness, angularity, can also be compensated.

Therefore, the embodiments of this disclosure effectively combine the possible cooling of FPGAs and processors as well as the cooling of other components or PCB peripherals located under the coldplate. Accordingly, additional air cooling of said components or peripherals may not be required. At the same time, the coldplate may fulfil the function of a shielding bonnet to meet the EMC requirements, especially through the targeted installation of wall structures.

It is important to note that, in the description as well as in the claims, the word “comprising” does not exclude other elements or steps and the indefinite article “a” or “an” does not exclude a plurality. A single element or other unit may fulfill the functions of several entities or items recited in the claims. Moreover, the disclosure with regard to any of the aspects is also relevant with regard to the other aspects of the disclosure.

Although the disclosure has been illustrated and described with respect to one or more implementations, equivalent alterations and modifications will occur to others skilled in the art upon the reading and understanding of this specification and the annexed drawings. In addition, while a particular feature of this disclosure may have been disclosed with respect to only one of several implementations, such feature may be combined with one or more other features of the other implementations as may be desired and advantageous for any given or particular application.

1. A coldplate system comprising:
at least one opening in a coldplate, and
at least one heat sink is inserted through the at least one opening and is connected to the coldplate via resilient mounting means,
wherein the at least one heat sink is provided with a heat transfer surface and an end with a heat dissipation structure,
wherein the heat dissipation structure is arranged within a space enclosed by the coldplate, and
wherein the resilient mounting means are configured to resiliently bias the heat transfer surface against a surface to be cooled when the coldplate system is mounted onto the surface.

2. The coldplate system according to claim 1,
wherein the coldplate further comprises a cooling fluid, an inlet, and an outlet, the cooling fluid being configured to flow through the coldplate via the inlet and the outlet.

3. The coldplate system according to claim 2,
wherein the cooling fluid is configured to flow through the heat dissipation structure of the at least one heat sink.

4. The coldplate system according to claim 1,
wherein the coldplate system further comprises a first sealing arrangement between the at least one opening in the coldplate and the at least one heat sink, the first sealing arrangement being configured to attach the at least one heat sink to the coldplate in a fluid-tight manner.

5. The coldplate system according to claim 1,
wherein the coldplate system further comprises a first retaining arrangement configured to retain the at least one heat sink to the coldplate corresponding to the at least one opening.

6. The coldplate system according to claim 1,
wherein the at least one heat sink further comprises:
one or more grooves for a first sealing arrangement between the at least one opening and the at least one heat sink,
one or more supports for the resilient mounting means, and
one or more recesses for a first retaining arrangement.

7. The coldplate system according to claim 2,
wherein the coldplate further comprises:
a first surface comprising the at least one opening,
a second surface configured to conceal the cooling fluid within the space enclosed by the coldplate, and
a second sealing arrangement configured to attach the first surface and the second surface in a fluid-tight manner.

8. The coldplate system according to claim 7,
wherein the first surface and/or the second surface comprises a plurality of guiding fins configured to control a flow of the cooling fluid within the coldplate.

9. The coldplate system according to claim 7,
wherein the first surface and/or the second surface comprises one or more flow divider configured to form respective flow channels for the cooling fluid within the coldplate.

10. The coldplate system according to claim 7,
wherein the coldplate further comprises a second retaining arrangement configured to retain the second surface to the first surface.

11. The coldplate system according to claim 7,
wherein the first surface comprises a peripheral segment protruding towards the surface to be cooled.

12. The coldplate system according to claim 2,
wherein the cooling fluid comprises or is a liquid cooling fluid and/or a gaseous cooling fluid.

13. The coldplate system according to claim 1,
wherein the resilient mounting means comprise or is a spring or a plurality of springs with variable pre-tensioning forces.

14. A cooling arrangement comprising:
the coldplate system according to claim 1, and
a printed circuit board comprising at least one element to be cooled,
wherein the resilient mounting means are configured to resiliently bias the heat transfer surface of the at least one heat sink against a surface of the at least one element to be cooled when the coldplate system is mounted onto the printed circuit board.

15. The cooling arrangement according to claim 14,
wherein the at least one element comprises or is a high power density integrated circuit.
